(19) United States
(12) Patent Application Publication
(10) Pub. No.: US 2025/0301641 A1
(43) Pub. Date: Sep. 25, 2025

(54) SEMICONDUCTOR STRUCTURE FOR 3D MEMORY DEVICE AND MANUFACTURING METHOD THEREOF

(71) Applicant: MACRONIX International Co., Ltd., Hsinchu (TW)

(72) Inventor: Chen-Wei Lu, Taoyuan City (TW)

(73) Assignee: MACRONIX International Co., Ltd., Hsinchu (TW)

(21) Appl. No.: 18/614,744

(22) Filed: Mar. 25, 2024

(51) Int. Cl. H10B 43/27; H10B 41/27

(52) U.S. Cl. CPC H10B 43/27; H10B 41/27

(57) ABSTRACT

Provided are a semiconductor structure for a three-dimensional (3D) memory and a manufacturing method thereof. The semiconductor structure may be used in a 3D AND flash memory. The semiconductor structure includes a substrate, an insulating wall and a stacked structure. The substrate has an array region and a staircase region surrounding the array region. The insulating wall is disposed on the substrate and surrounds the array region and the staircase region. The stacked structure is disposed on the substrate in the array region and the staircase region, and includes a plurality of insulating layers and a plurality of conductive layers alternately stacked. The plurality of insulating layers and the plurality of conductive layers extend conformally onto the insulating wall.

### BACKGROUND

### Technical Field

The present invention relates to a semiconductor structure and a manufacturing method thereof, and in particular, to a semiconductor structure for a three-dimensional (3D) memory and a manufacturing method thereof.

### Description of Related Art

A non-volatile memory, such as a flash memory, has the advantage that the stored data will not disappear after power off, so it has become a kind of memory widely used in personal computers and other electronic apparatuses.

In the current 3D flash memory, in the stacked structure in the staircase region, each word line is electrically connected to the upper circuit layer through the contact-on-array (COA). The COAs are important keys to operating memory cells at different levels.

Generally speaking, during the formation of the COAs, the COA holes exposing the word lines are formed in the stacked structure in the staircase region through the etching process. Corresponding to the word lines at different levels, the COA holes have different depths, so a longer etching time is required to form the deeper COA holes. As a result, during the etching process, the word line(s) located at the upper portion of the stacked structure may be easily damaged by over-etching. In addition, when forming the COA holes, if the alignment is insufficient, the positions of the formed COA hole mat be shifted, causing the bridging problem on the word lines at different levels.

### SUMMARY

The present invention provides a semiconductor structure for a 3D memory and a manufacturing method thereof, wherein an insulating wall is formed on the substrate and surrounds the array region and staircase region, and a stacked structure including a plurality of insulating layer and a plurality of conductive layer alternately attacked is formed on the substrate in the array region and staircase region and conformally extends onto the insulating wall.

The semiconductor structure for a 3D memory of the present invention includes a substrate, an insulating wall and a stacked structure. The substrate has an array region and a staircase region surrounding the array region. The insulating wall is disposed on the substrate and surrounds the array region and the staircase region. The stacked structure is disposed on the substrate in the array region and the staircase region, and includes a plurality of insulating layers and a plurality of conductive layers alternately stacked. The plurality of insulating layers and the plurality of conductive layers extend conformally onto the insulating wall.

In an embodiment of the semiconductor structure of the present invention, the insulating wall has a staircase profile and includes a plurality of steps, and the plurality of insulating layers and the plurality of conductive layers conformally extend onto the plurality of steps.

In an embodiment of the semiconductor structure of the present invention, each of the plurality of steps includes a top surface and a sidewall; each of the plurality of insulating layers and the plurality of conductive layers except the uppermost insulating layer includes a body portion and an extension portion connected to the body portion, and the uppermost insulating layer includes the body portion; the extension portion of each of the plurality of insulating layers and the plurality of conductive layers except the uppermost insulating layer and the uppermost conductive layer includes at least one first portion and at least one second portion, and the extension portion of the conductive layer includes one second portion, wherein the first portion is disposed corresponding to the top surface, and the second portion is disposed corresponding to the sidewall; and the uppermost second portion of each of the conductive layers except the uppermost conductive layer and the second portion of the uppermost conductive layer are exposed by the uppermost first portion of each of the insulating layers except the uppermost insulating layer and the body portion of the uppermost insulating layer.

In an embodiment of the semiconductor structure of the present invention, top surfaces of the uppermost second portion of each of the conductive layers except the uppermost conductive layer and the second portion of the uppermost conductive layer are coplanar with top surfaces of the uppermost first portion of each of the insulating layers except the uppermost insulating layer and the body portion of the uppermost insulating layer.

In an embodiment of the semiconductor structure of the present invention, each conductive layer has a first thickness, each insulating layer has a second thickness, the top surface of each step has a depth, and a distance between centers of the second portions of two adjacent conductive layers is sum of the first thickness, the second thickness and the depth.

In an embodiment of the semiconductor structure of the present invention, an end of the extension portion of the conductive layer is connected to an end of the body portion.

In an embodiment of the semiconductor structure of the present invention, the semiconductor structure further includes a supporting pillar penetrating through the stacked structure from an end of the extension portion of the insulating layer and disposed on the substrate.

In an embodiment of the semiconductor structure of the present invention, the supporting pillar further penetrates the insulating wall.

In an embodiment of the semiconductor structure of the present invention, the semiconductor structure further includes a supporting wall penetrating through the stacked structure and the insulating wall and disposed on the substrate, and extending in a plane direction of the substrate.

In an embodiment of the semiconductor structure of the present invention, the semiconductor structure further includes a plurality of contacts respectively connected to an end of a corresponding conductive layer.

The manufacturing method of the semiconductor structure for a 3D memory of the present invention includes the following steps. A substrate is provided, wherein the substrate has an array region and a staircase region surrounding the array region. An insulating wall is formed to surround the array region and the staircase region on the substrate. A stacked structure is formed on the substrate in the array region and the staircase region, wherein the stacked structure includes a plurality of insulating layers and a plurality of conductive layers alternately stacked. The plurality of insulating layers and the plurality of conductive layers conformally extend onto the insulating wall.

In an embodiment of the manufacturing method of the present invention, the insulating wall has a staircase profile and includes a plurality of steps, and the plurality of insulating layers and the plurality of conductive layers conformally extend onto the plurality of steps.

In an embodiment of the manufacturing method of the present invention, each of the plurality of steps includes a top surface and a sidewall; each of the plurality of insulating layers and the plurality of conductive layers except the uppermost insulating layer includes a body portion and an extension portion connected to the body portion, and the uppermost insulating layer includes the body portion; the extension portion of each of the plurality of insulating layers and the plurality of conductive layers except the uppermost insulating layer and the uppermost conductive layer includes at least one first portion and at least one second portion, and the extension portion of the conductive layer includes one second portion, wherein the first portion is disposed corresponding to the top surface, and the second portion is disposed corresponding to the sidewall; and the uppermost second portion of each of the conductive layers except the uppermost conductive layer and the second portion of the uppermost conductive layer are exposed by the uppermost first portion of each of the insulating layers except the uppermost insulating layer and the body portion of the uppermost insulating layer.

In an embodiment of the manufacturing method of the present invention, top surfaces of the uppermost second portion of each of the conductive layers except the uppermost conductive layer and the second portion of the uppermost conductive layer are coplanar with top surfaces of the uppermost first portion of each of the insulating layers except the uppermost insulating layer and the body portion of the uppermost insulating layer.

In an embodiment of the manufacturing method of the present invention, each conductive layer has a first thickness, each insulating layer has a second thickness, the top surface of each step has a depth, and a distance between centers of the second portions of two adjacent conductive layers is sum of the first thickness, the second thickness and the depth.

In an embodiment of the manufacturing method of the present invention, an end of the extension portion of the conductive layer is connected to an end of the body portion.

In an embodiment of the manufacturing method of the present invention, the manufacturing method further includes forming a supporting pillar penetrating through the stacked structure from an end of the extension portion of the insulating layer and disposed on the substrate.

In an embodiment of the manufacturing method of the present invention, the supporting pillar further penetrates the insulating wall.

In an embodiment of the manufacturing method of the present invention, a forming method of the stacked structure includes the following steps. After forming the insulating wall, an initial stacked structure is formed on the substrate surrounded by the insulating wall, wherein the initial stacked structure includes the plurality of insulating layers and a plurality of sacrificial layers alternately stacked, and the plurality of insulating layers and the plurality of sacrificial layers conformally extend onto the plurality of steps. The plurality of sacrificial layers are replaced with the plurality of conductive layers.

In an embodiment of the manufacturing method of the present invention, the insulating layer is a silicon oxide layer, and the sacrificial layer is a silicon nitride layer.

In an embodiment of the manufacturing method of the present invention, the manufacturing method further includes forming a supporting wall penetrating through the stacked structure and the insulating wall and extending in a plane direction of the substrate after forming the initial stacked structure and before replacing the plurality of sacrificial layers with the plurality of conductive layers.

In an embodiment of the manufacturing method of the present invention, the manufacturing method further includes forming a contact at an end of each conductive layer.

Based on the above, in the semiconductor structure for the 3D memory and the manufacturing method thereof of the present invention, the insulating wall is formed on the substrate and surrounds the array region and the staircase region, and the stacked structure including a plurality of insulating layer and a plurality of conductive layer alternately attacked is formed on the substrate in the array region and staircase region and conformally extends onto the insulating wall. Therefore, when the semiconductor structure of the present invention is applied to a memory device, the conductive layer in the stacked structure may be used as the word line and the contact connected to the word line at the same time, that is, the word line and the contact are integrated. In this way, the alignment shift between the word line and the contact may be effectively avoided, and there is no need to form contact holes with different depths to form the contacts connected to the word lines at different levels. As a result, the damage of the word line(s) caused by over-etching during the etching process for forming the contact holes with different depths.

### BRIEF DESCRIPTION OF THE DRAWINGS

FIGS. 1A to 1E are schematic cross-sectional views of the manufacturing process of the semiconductor structure of the first embodiment of the present invention.

FIG. 2 is a top view of the substrate in FIG. 1A.

FIG. 3 is a schematic cross-sectional view of the semiconductor structure of the second embodiment of the present invention.

FIGS. 4A and 4B are respectively a top view and a cross-sectional view of the semiconductor structure of the third embodiment of the present invention.

FIG. 5 is a schematic top view of the semiconductor structure of the fourth embodiment of the present invention.

FIG. 6 is a schematic top view of the semiconductor structure of the fifth embodiment of the present invention.

FIG. 7 is a schematic top view of the semiconductor structure of the sixth embodiment of the present invention.

FIG. 8 is a circuit diagram of the 3D AND flash memory array including the semiconductor structure of present invention.

### DESCRIPTION OF THE EMBODIMENTS

The embodiments are listed below and described in detail with the accompanying drawings, but the provided embodiments are not intended to limit the scope of the present invention. In addition, the drawings are for illustration purposes only and are not drawn to original scale. In order to facilitate understanding, the same devices will be described with the same symbols in the following descriptions.

In the text, the terms mentioned in the text, such as “comprising”, “including”, “containing” and “having” are all open-ended terms, i.e., meaning “including but not limited to”.

When using terms such as “first” and “second” to describe elements, it is only used to distinguish the elements from each other, and does not limit the order or importance of the devices. Therefore, in some cases, the first element may also be called the second element, the second element may also be called the first element, and this is not beyond the scope of the present invention.

In addition, the directional terms, such as “on”, “above”, “under” and “below” mentioned in the text are only used to refer to the direction of the drawings, and are not used to limit the present invention.

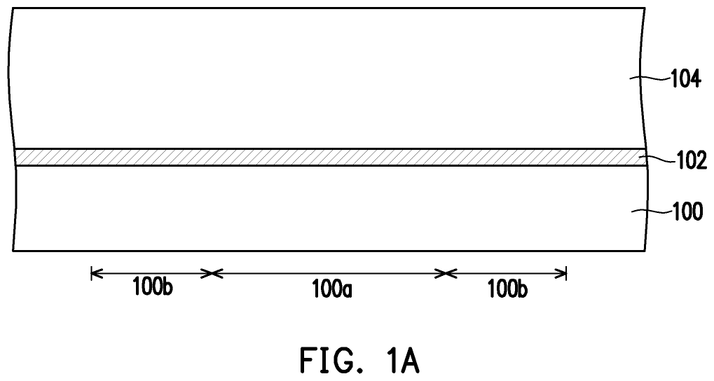

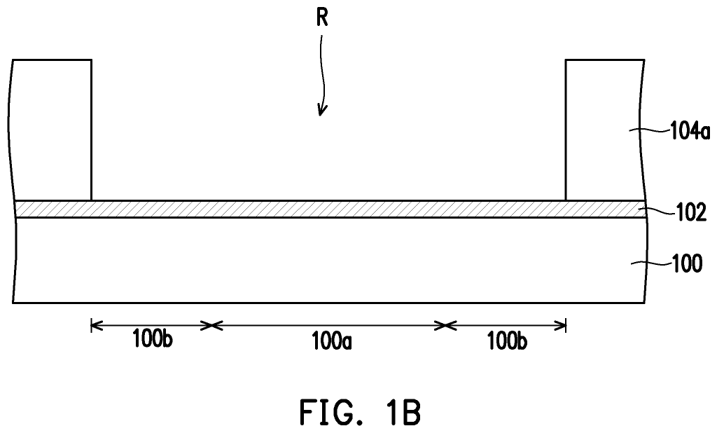

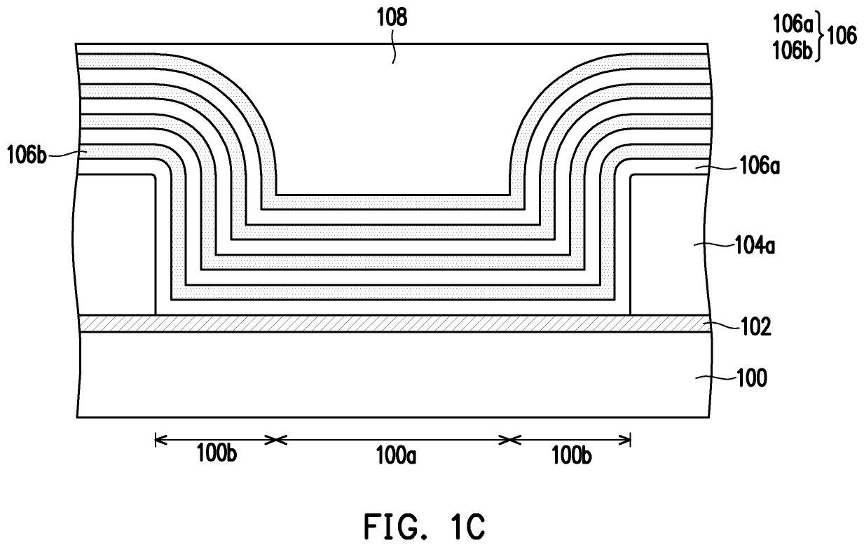

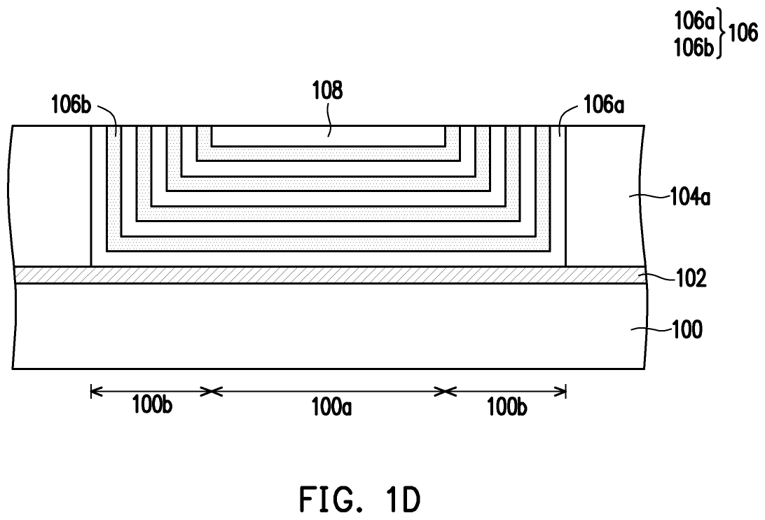

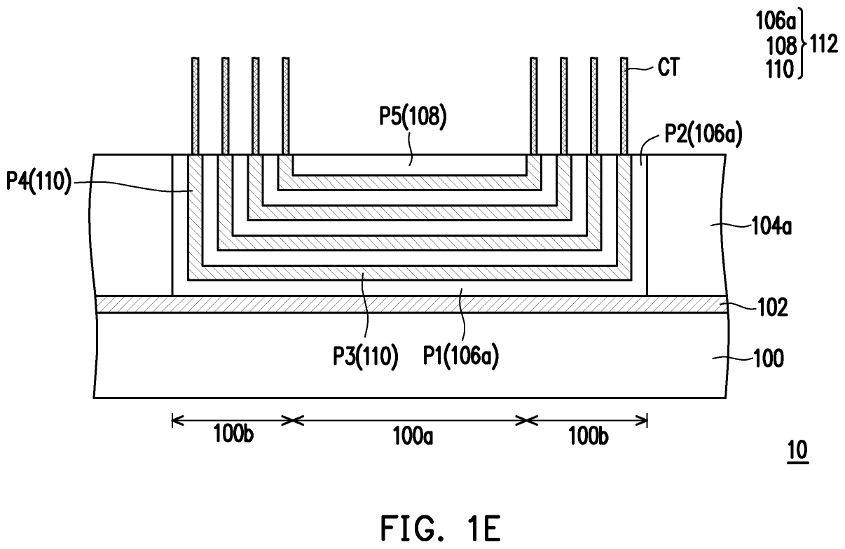

FIGS. 1A to 1E are schematic cross-sectional views of the manufacturing process of the semiconductor structure of the first embodiment of the present invention.

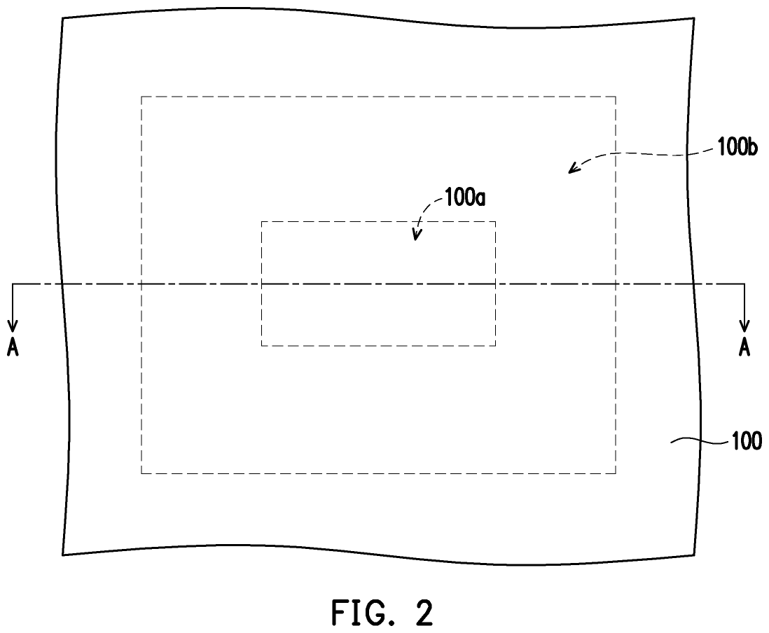

Referring to FIG. 1A, a substrate 100 is provided. In the present embodiment, the substrate 100 may include a silicon substrate. The substrate 100 has an array region 100a and a staircase region 100b. As shown in FIG. 2, from the top view of the substrate 100, the staircase region 100b surrounds the array region 100a, and the array region 100a and the staircase region 100b form a memory device region. In the present embodiment, FIGS. 1A to 1E are schematic cross-sectional views drawn along the line A-A in FIG. 2.

In the present embodiment, the substrate 100 may also include a device structure layer (not shown) formed on the silicon substrate. The device structure layer may include various commonly known semiconductor devices. For example, the device structure layer may include a transistor formed at the surface of the silicon substrate, an interconnect structure electrically connected to the transistor, and a dielectric layer covering the transistor and the interconnect structure, but present invention is not limited thereto.

Then, a conductive layer 102 is formed on the substrate 100. In the present embodiment, the conductive layer 102 may be a ground layer. The conductive layer 102 may be a polysilicon layer, but the present invention is not limited thereto. After that, an insulating layer 104 is formed on the conductive layer 102. In the present embodiment, the insulating layer 104 is, for example, a silicon oxide layer, but the present invention is not limited thereto.

Referring to FIG. 1B, a part of the insulating layer 104 is removed to form a recess R in the insulating layer 104, and the remaining insulating layer 104 forms an insulating wall 104a. In the present embodiment, the recess R is a region where a memory device is to be formed. That is, the insulating wall 104a is formed on the substrate 100 and surrounds the array region 100a and the staircase region 100b.

Referring to FIG. 1C, an initial stacked structure 106 is conformally formed on the substrate 100 to cover the exposed conductive layer 102 and the sidewalls and the top surface of the insulating wall 104a. The initial stacked structure 106 includes a plurality of insulating layer 106a and a plurality of sacrificial layer 106b stacked alternately, and the bottom of the stacked structure 106 is the insulating layer 106a. In FIG. 1C, the numbers of the insulating layer 106a and the sacrificial layer 106b are only exemplary, and the present invention is not limited thereto. In the present embodiment, the insulating layer 106a is a silicon oxide layer, and the sacrificial layer 106b is a silicon nitride layer, but the present invention is not limited thereto. After the initial stacked structure 106 is formed, an insulating layer 108 is formed on the initial stacked structure 106 to fill the recess R. In the present embodiment, the insulating layer 108 is a silicon oxide layer.

Referring to FIG. 1D, the initial stacked structure 106 and insulating layer 108 outside the recess R are removed. At this time, the top surfaces of the remaining insulating layers 106a, the remaining sacrificial layers 106b, the top surface of the remaining insulating layer 108 and the top surface of the insulating wall 104a in the recess R are coplanar. In the present embodiment, the method for removing the initial stacked structure 106 and insulating layer 108 outside the recess R is, for example, performing an etching-back process, but the present invention is not limited thereto. In addition, during removing the initial stack structure 106 and the insulating layer 108 outside the recess R, a part of the insulating wall 104a may be slightly removed, so that the insulating wall 104a has a reduced height.

Referring to FIG. 1E, a replacement process is performed to replace the sacrificial layers 106b with conductive layers 110. The conductive layer 110 include a metal layer, such as a tungsten layer. The replacement process is well known to those skilled in the art and will not be described in detail. In the present embodiment, the stacked insulating layers 106a, the conductive layers 110 and the insulating layer 108 form a stacked structure 112 in recess R. In other words, the stacked structure 112 is formed in the array region 100a and the staircase region 100b, and conformally extends onto the sidewall of the insulating wall 104a. At this time, the ends of the conductive layers 110 are exposed. In this way, a semiconductor structure 10 of the present embodiment is formed.

In addition, after the semiconductor structure 10 is formed, contacts CT respectively connected to the ends of the conductive layers 110 may be formed.

The semiconductor structure 10 of the present embodiment may be applied to a 3D AND flash memory. When the semiconductor structure 10 of the present embodiment is applied to a 3D AND flash memory, the processes for forming channel structures, supporting pillars, supporting walls, etc. may be performed, which are well known to those skilled in the art and will not be described.

When the semiconductor structure 10 of the present embodiment is applied to a memory device, the conductive layer 110 in the stacked structure 112 may be used as a word line and a contact connected to the word line at the same time. In detail, as shown in FIG. 1E, in the stacked structure 112, each insulating layer 106a includes a body portion P1 extending in a plane direction of the substrate 100 and an extension portion P2 connected to the end of the body portion P1 and extending in a direction perpendicular to the plane direction of the substrate 100. The extension portion P2 extends from the body portion P1 onto the sidewall of the insulating wall 104a. Furthermore, the uppermost insulating layer 108 in the stacked structure 112 includes a body portion P5 without an extension portion.

Furthermore, in the stacked structure 112, each conductive layer 110 includes a body portion P3 disposed parallel to the body portion P1 and an extension portion P4 connected to the end of the body portion P3 and disposed parallel to the extension portion P2. The body portion P3 may be used as a word line, and the extension portion P2 may be used as a contact connected to the word line. That is, in the semiconductor structure 10, the word line and the contact are integrated, and there is no interface therebetween. Therefore, the alignment shift between the word line and the contact may be effectively avoid. In addition, since the word line and the contact are integrally formed, there is no need to form contact holes with different depths to form contacts connected to the word lines at different levels. As a result, the damage of the word line(s) caused by over-etching during the etching process for forming the contact holes with different depths. In other words, in the present embodiment, as shown in FIG. 1E, the landing areas for connecting with the contacts CT may be located at the same level.

In the stacked structure 112, the ends of the extension portions P4 of the conductive layers 110 are exposed by the extension portions P2 of the insulating layers 106a and the body portion P5 of the insulating layer 108, so that the word lines (the body portions P3) may be electrically connected to other devices, such as contacts CT, through the extension Portions P4.

In the present embodiment, the insulating wall 104a has a substantially vertical sidewall, so that the extension portions P4 of the conductive layers 110 may vertically extend upward corresponding to the sidewall of the insulating wall 104a, but the present invention is not limited thereto. In another embodiment, the insulating wall 104a may have an inclined sidewall. In other embodiments, the insulating wall may have a staircase profile such that the extension portions of the conductive layers 110 may extend upward corresponding to the sidewalls and top surfaces of the steps of the insulating wall. This will be explained in detail below.

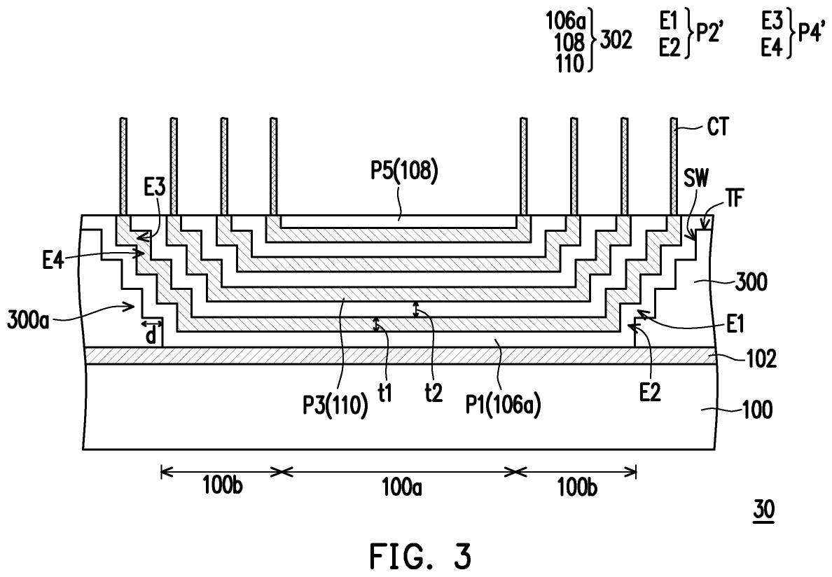

FIG. 3 is a schematic cross-sectional view of the semiconductor structure of the second embodiment of the present invention. In the present embodiment, devices that are the same as in the first embodiment will be represented by the same reference symbols and will not be explained again. In addition, the manufacturing method of the semiconductor structure of the second embodiment is similar to that of the first embodiment, and the only difference is the profiles of the insulating walls. Therefore, the manufacturing method of the semiconductor structure of the second embodiment will not be described further.

Referring to FIG. 3, in the semiconductor structure 30 of the present embodiment, as the insulating wall 104a, the insulating wall 300 is formed on the substrate 100 and surrounds the array region 100a and the staircase region 100b. The insulating wall 300 has a staircase profile and includes a plurality of steps 300a. Each step 300a has a top surface TF and a sidewall SW, and the top surface TF has a depth d. In FIG. 3, the number of the steps 300a is only exemplary, and the present invention is not limited thereto.

The stacked structure 302 is formed in the array region 100a and the staircase region 100b, and conformally extends onto the steps 300a of the insulating wall 300. In the present embodiment, the stacked structure 302 includes the insulating layers 106a, the conductive layers 110 and the insulating layer 108 stacked.

In the stacked structure 302, except the uppermost insulating layer 108, each of the insulating layers 106a includes the body portion P1 and an extension portion P2′ connected to the body portion P1, and each of the conductive layers 110 includes the body portion P3 and an extension portion P4′ connected to the body portion P3. The uppermost insulating layer 108 includes the body portion P5. One end of the extension portion P2′ is connected to the end of the body portion P1, and one end of the extension portion P4′ is connected to the end of the body portion P3. In addition, except the uppermost insulating layer 108 and the uppermost conductive layer 110, each of the extension portions P2′ of the insulating layers 106a includes at least one first portion E1 disposed corresponding to the top surface TF of the step 300a and at least one second portion E2 disposed corresponding to the sidewall SW of the step 300a, and each of the extension portions P4′ of the conductive layers 110 includes at least one first portion E3 disposed corresponding to the top surface TF disposed of the step 300a and at least one second portion E4 disposed corresponding to the sidewall SW of step 300a. The extension portion P4′ of the upper conductive layer 110 includes one second portion E4.

In the present embodiment, in the stacked structure 302, the second portion E4 of the uppermost conductive layer 110 and the uppermost second portions E4 of the remaining conductive layers 110 are exposed by the uppermost first portions E1 of the insulating layers 106a and the body portion P5 of the insulating layer 108. That is, the top surface of the second portion E4 of the uppermost conductive layer 110 and the top surfaces of the uppermost second portions E4 of the remaining conductive layers 110 are coplanar with the top surfaces of the uppermost first portions E1 of the insulating layers 106a and the top surface of the body portion P5 of the insulating layer 108, but the present invention is not limited thereto.

In other embodiments, depending on the actual situation, the uppermost conductive layer may only include the body portion P3 without the extension portion, there is no insulating layer 108, and the body portion P3 of the uppermost conductive layer 110 and the uppermost first portions E3 of the remaining conductive layers 110 are exposed by the uppermost second portions E2 of the insulating layers 106a. That is, the top surface of the body portion P3 of the uppermost conductive layer 110 and the top surfaces of the uppermost first portions E4 of the remaining conductive layers 110 are coplanar with the top surfaces of the uppermost second portions E2 of the insulating layers 106a.

Furthermore, in the stacked structure 302, the conductive layers 110 has the same thickness t1 and the insulating layers 106a has the same thickness t2. Therefore, the distance between the centers of the second portions E4 of two adjacent conductive layers 110 is the sum of the thickness t1, the thickness t1 and the depth d. In this way, there may be a larger pitch between the conductive layers 110 exposed at the top surface of the stacked structure 302, so that there may be a larger distance between the subsequently formed contacts CT connected to the conductive layers 110, so as to avoid the bridging problem caused by the distance between the contacts CT being too small or the shifted positions of the contacts CT.

The semiconductor structure 30 of the present embodiment may be applied to a 3D AND flash memory. When the semiconductor structure 30 of the present embodiment is applied to a 3D AND flash memory, the required 3D AND flash memory process may be performed to form channel structures, supporting pillars, supporting walls, etc. The following will take the semiconductor structure 30 as an example to illustrate these structures.

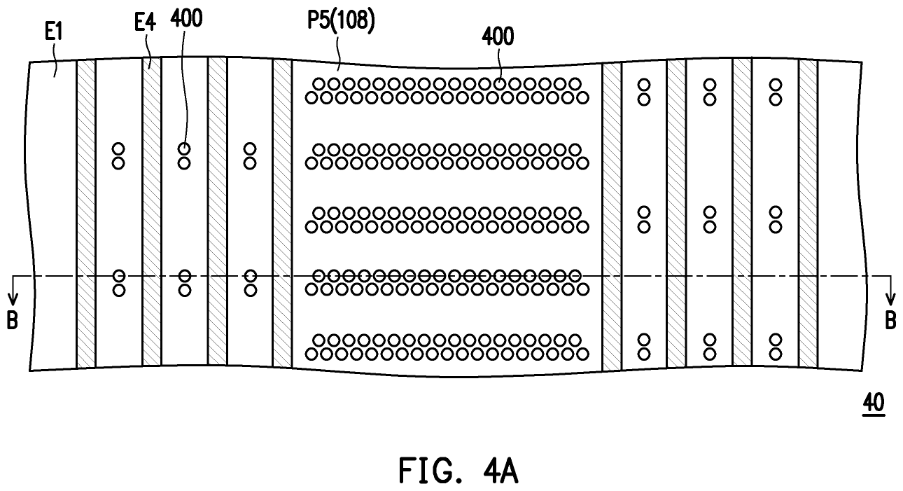

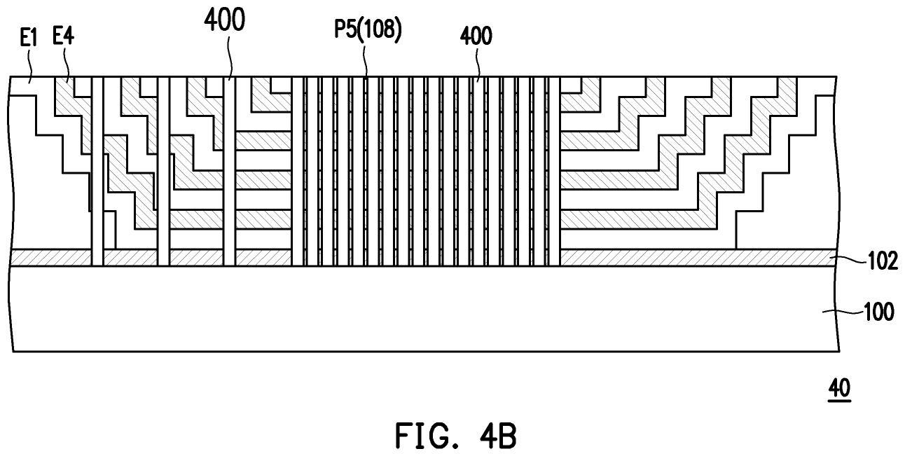

FIGS. 4A and 4B are respectively a top view and a cross-sectional view of the semiconductor structure of the third embodiment of the present invention. In the present embodiment, devices that are the same as in the second embodiment will be represented by the same reference symbols and will not be explained again.

Referring to FIGS. 4A and 4B, in the semiconductor structure 40, supporting pillars 400 are disposed on the substrate 100, and penetrate through the stacked structure 302 and the conductive layer 102 thereunder from the insulating layer 108 and from the end of the insulating layer 106a (the uppermost first portion E1). In addition, some of the supporting pillars 400 not only penetrate through the stacked structure 302 and the conductive layer 102, but also penetrate through the insulating wall 300 under the stacked structure 302. In FIG. 4A, the number and layout of the supporting pillars 400 are only exemplary, and the present invention is not limited thereto. The material of the supporting pillar 400 includes insulating material, such as silicon oxide. In addition, depending on actual needs, the supporting pillar 400 may be composed of a conductive pillar and an insulating material encapsulating the conductive pillar.

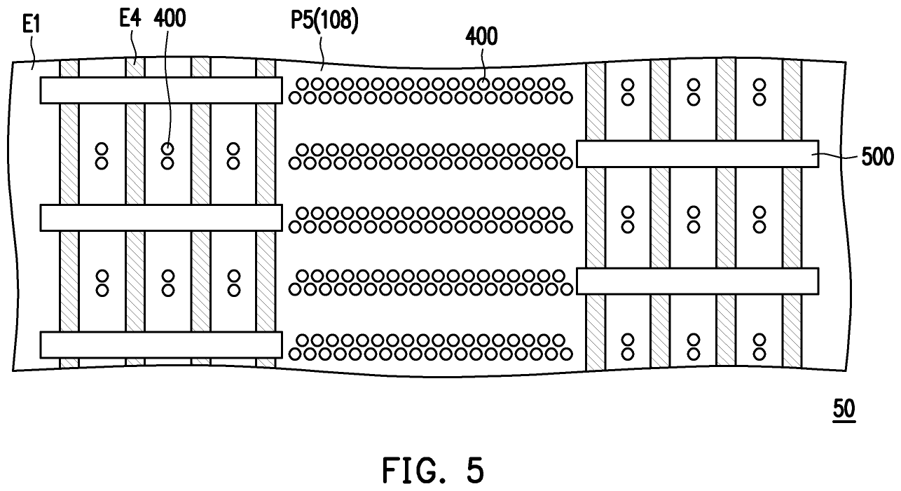

FIG. 5 is a schematic top view of the semiconductor structure of the fourth embodiment of the present invention. In the present embodiment, devices that are the same as in the third embodiment will be represented by the same reference symbols and will not be explained again. Referring to FIG. 5, the difference between the present embodiment and the third embodiment is that the semiconductor structure 50 further includes supporting walls 500. The supporting walls 500 are disposed on the substrate 100 and extend in a plane direction of the substrate 100. In addition, the supporting wall 500 penetrates the stacked structure 302, the insulating wall 300 and the conductive layer 102. In FIG. 5, the number and layout of the supporting walls 500 are only exemplary, and the present invention is not limited thereto. The material of the supporting wall 500 includes insulating material, such as silicon oxide. The supporting wall 500 is formed by, for example, forming a trench penetrating through the initial stacked structure 106 and the insulating wall 300 before the replacement process described in FIG. 1E, and then filling the trench with insulating material.

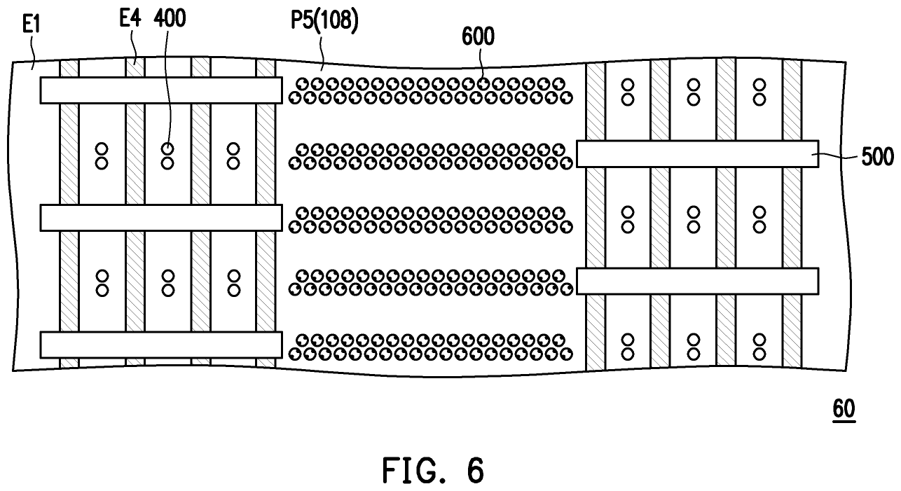

FIG. 6 is a schematic top view of the semiconductor structure of the fifth embodiment of the present invention. In the present embodiment, devices that are the same as in the fourth embodiment will be represented by the same reference symbols and will not be explained again.

Referring to FIG. 6, the difference between the present embodiment and the fourth embodiment is that the semiconductor structure 60 further includes channel structures 600. The channel structures 600 are disposed in the array region 100a of the substrate 100 and penetrating through the stacked structure 302 and the conductive layer 102. In FIG. 6, the number and layout of channel structures 600 are only exemplary, and the present invention is not limited thereto. The channel structure 600 may include a channel pillar, a charge storage layer, a source pillar, a drain pillar, etc., which is well known to those skilled in the art and will not be described again.

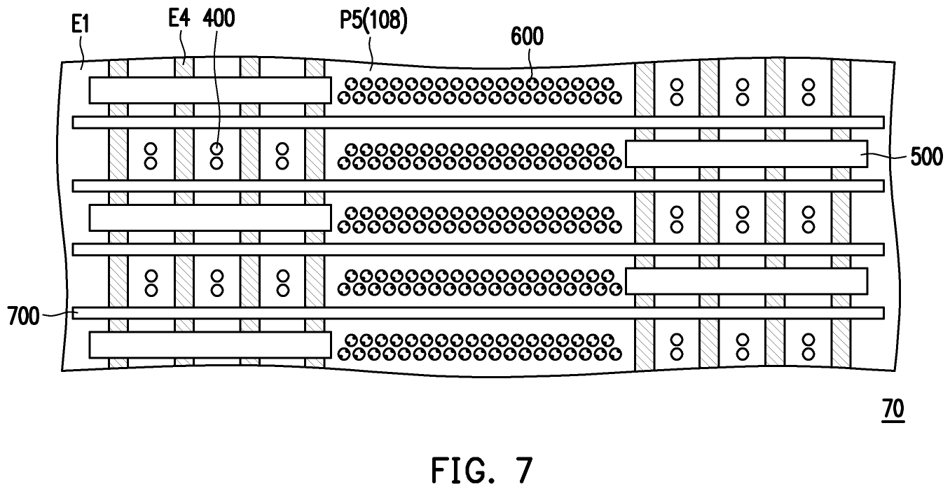

FIG. 7 is a schematic top view of the semiconductor structure of the sixth embodiment of the present invention. In the present embodiment, devices that are the same as in the fifth embodiment will be represented by the same reference symbols and will not be explained again.

Referring to FIG. 7, the difference between the present embodiment and the fifth embodiment is that in the semiconductor structure 60, the stacked structure 302 has slits 700. The slit 700 penetrates through the stacked structure 302 and the conductive layer 102. The slits 700 divide the stacked structure 302 into a plurality of blocks, which is well known to those skilled in the art and will not be described again.

Hereinafter, a circuit structure of a 3D memory array MSC including the semiconductor structure of the present embodiment will be described.

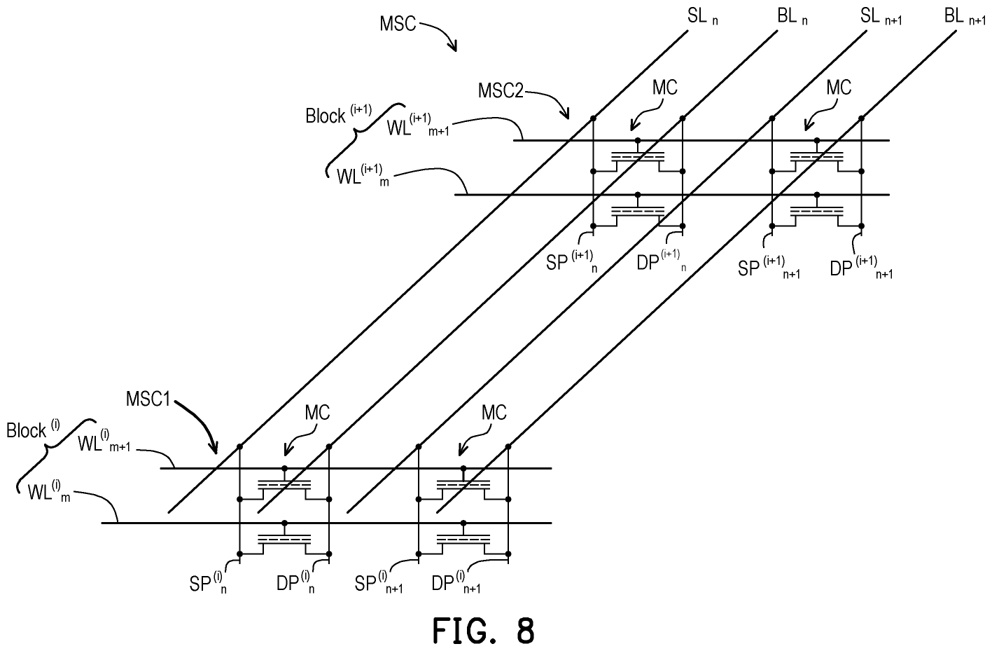

FIG. 8 is a circuit diagram of the 3D AND flash memory array including the semiconductor structure of present invention.

Referring to FIG. 8, two blocks BLOCK⁽ⁱ⁾ and BLOCK⁽ⁱ⁺¹⁾ of a vertical AND memory array MSC are arranged in rows and columns. The block BLOCK⁽ⁱ⁾ includes a memory array MSC1. A row (e.g., an (m+1)^{th} row) of the memory array MSC1 is a set of AND memory cells MC having a common word line (e.g., WL⁽ⁱ⁾ₘ₊₁). The AND memory cells MC of the memory array MSC1 in each row (e.g., the (m+1)^{th} row) correspond to a common word line (e.g., WL⁽ⁱ⁾ₘ₊₁) and are coupled to different source pillars (e.g., SP⁽ⁱ⁾ₙ and SP⁽ⁱ⁾ₙ₊₁) and drain pillars (e.g., DP⁽ⁱ⁾ₙ and DP⁽ⁱ⁾ₙ₊₁), so that the AND memory cells MC are logically arranged in a row along the common word line (e.g., WL⁽ⁱ⁾ₘ₊₁).

A column (e.g., an n^{th} column) of the memory array MSC1 is a set of AND memory cells MC having a common source pillar (e.g., SP⁽ⁱ⁾ₙ) and a common drain pillar (e.g., DP⁽ⁱ⁾ₙ). The AND memory cells MC of the memory array MSC1 in each column (e.g., the n^{th} column) correspond to different word lines (e.g., WL⁽ⁱ⁾ₘ₊₁ and WL⁽ⁱ⁾ₘ) and are coupled to a common source pillar (e.g., SP⁽ⁱ⁾ₙ) and a common drain pillar (e.g., DP⁽ⁱ⁾ₙ). Hence, the AND memory cells MC of the memory array MSC1 are logically arranged in a column along the common source pillar (e.g., SP⁽ⁱ⁾ₙ) and the common drain pillar (e.g., DP⁽ⁱ⁾ₙ). In the physical layout, according to the manufacturing method as applied, the columns or rows may be twisted and arranged in a honeycomb pattern or other patterns for high density or other reasons.

In FIG. 8, in the block BLOCK⁽ⁱ⁾, the AND memory cells MC in the n^{th} column of the memory array MSC1 share a common source pillar (e.g., SP⁽ⁱ⁾ₙ) and a common drain pillar (e.g., DP⁽ⁱ⁾ₙ). The AND memory cells MC in an (n+1)^{th} column share a common source pillar (e.g., SP⁽ⁱ⁾ₙ₊₁) and a common drain pillar (e.g., DP⁽ⁱ⁾ₙ₊₁).

The common source pillar (e.g., SP⁽ⁱ⁾ₙ) is coupled to a common source line (e.g., SLₙ) and the common drain pillar (e.g., DP⁽ⁱ⁾ₙ) is coupled to a common bit line (e.g., BLₙ). The common source pillar (e.g., SP⁽ⁱ⁾ₙ₊₁) is coupled to a common source line (e.g., SLₙ₊₁) and the common drain pillar (e.g., DP⁽ⁱ⁾ₙ₊₁) is coupled to a common bit line (e.g., BLₙ₊₁).

Likewise, the block BLOCK⁽ⁱ⁺¹⁾ includes a memory array MSC2, which is similar to the memory array MSC1 in the block BLOCK⁽ⁱ⁾. A row (e.g., an (m+1)^{th} row) of the memory array MSC2 is a set of AND memory cells MC having a common word line (e.g., WL⁽ⁱ⁺¹⁾ₘ₊₁). The AND memory cells MC of the memory array MSC2 in each row (e.g., the (m+1)^{th} row) correspond to a common word line (e.g., WL⁽ⁱ⁺¹⁾ₘ₊₁) and are coupled to different source pillars (e.g., SP⁽ⁱ⁺¹⁾ₙ and SP⁽ⁱ⁺¹⁾ₙ₊₁) and drain pillars (e.g., DP⁽ⁱ⁺¹⁾ₙ and DP⁽ⁱ⁺¹⁾ₙ₊₁). A column (e.g., an n^{th} column) of the memory array MSC2 is a set of AND memory cells MC having a common source pillar (e.g., SP⁽ⁱ⁺¹⁾ₙ) and a common drain pillar (e.g., DP⁽ⁱ⁺¹⁾ₙ). The AND memory cells MC are integrated and connected in parallel, and thus may be also referred to as a memory string. The AND memory cells MC of the memory array MSC2 in each column (e.g., the n^{th} column) correspond to different word lines (e.g., WL⁽ⁱ⁺¹⁾ₘ₊₁ and WL⁽ⁱ⁺¹⁾ₘ) and are coupled to a common source pillar (e.g., SP⁽ⁱ⁺¹⁾ₙ) and a common drain pillar (e.g., DP⁽ⁱ⁺¹⁾ₙ). Hence, the AND memory cells MC of the memory array MSC2 are logically arranged in a column along the common source pillar (e.g., SP⁽ⁱ⁺¹⁾ₙ) and the common drain pillar (e.g., DP⁽ⁱ⁺¹⁾ₙ).

The block BLOCK⁽ⁱ⁺¹⁾ and the block BLOCK⁽ⁱ⁾ share source lines (e.g., SLₙ and SLₙ₊₁) and bit lines (e.g., BLₙ and BLₙ₊₁). Therefore, the source line SLₙ and the bit line BLₙ are coupled to the n^{th} column of AND memory cells MC in the AND memory array MSC1 of the block BLOCK⁽ⁱ⁾, and are coupled to the n^{th} column of AND memory cells MC in the AND memory array MSC2 of the block BLOCK⁽ⁱ⁺¹⁾. Similarly, the source line SLₙ₊₁ and the bit line BLₙ₊₁ are coupled to the (n+1)^{th} column of AND memory cells MC in the AND memory array MSC1 of the block BLOCK⁽ⁱ⁾, and are coupled to the (n+1)^{th} column of AND memory cells MC in the AND memory array MSC2 of the block BLOCK⁽ⁱ⁺¹⁾.

It will be apparent to those skilled in the art that various modifications and variations may be made to the disclosed embodiments without departing from the scope or spirit of the invention. In view of the foregoing, it is intended that the invention covers modifications and variations provided that they fall within the scope of the following claims and their equivalents.

What is claimed is:

1. A semiconductor structure for a three-dimensional (3D) memory, comprising:
a substrate, having an array region and a staircase region surrounding the array region;
an insulating wall, disposed on the substrate and surrounding the array region and the staircase region; and
a stacked structure, disposed on the substrate in the array region and the staircase region, and comprising a plurality of insulating layers and a plurality of conductive layers alternately stacked,
wherein the plurality of insulating layers and the plurality of conductive layers conformally extend onto the insulating wall.

2. The semiconductor structure of claim 1, wherein the insulating wall has a staircase profile and comprises a plurality of steps, and the plurality of insulating layers and the plurality of conductive layers conformally extend onto the plurality of steps.

3. The semiconductor structure of claim 2, wherein:
each of the plurality of steps comprises a top surface and a sidewall,
each of the plurality of insulating layers and the plurality of conductive layers except the uppermost insulating layer comprises a body portion and an extension portion connected to the body portion, and the uppermost insulating layer comprises the body portion,
the extension portion of each of the plurality of insulating layers and the plurality of conductive layers except the uppermost insulating layer and the uppermost conductive layer comprises at least one first portion and at least one second portion, and the extension portion of the conductive layer comprises one second portion, wherein the first portion is disposed corresponding to the top surface, and the second portion is disposed corresponding to the sidewall, and
the uppermost second portion of each of the conductive layers except the uppermost conductive layer and the second portion of the uppermost conductive layer are exposed by the uppermost first portion of each of the insulating layers except the uppermost insulating layer and the body portion of the uppermost insulating layer.

4. The semiconductor structure of claim 3, wherein top surfaces of the uppermost second portion of each of the conductive layers except the uppermost conductive layer and the second portion of the uppermost conductive layer are coplanar with top surfaces of the uppermost first portion of each of the insulating layers except the uppermost insulating layer and the body portion of the uppermost insulating layer.

5. The semiconductor structure of claim 3, wherein:
each conductive layer has a first thickness,
each insulating layer has a second thickness,
the top surface of each step has a depth, and
a distance between centers of the second portions of two adjacent conductive layers is sum of the first thickness, the second thickness and the depth.

6. The semiconductor structure of claim 3, wherein an end of the extension portion of the conductive layer is connected to an end of the body portion.

7. The semiconductor structure of claim 3, further comprising a supporting pillar penetrating through the stacked structure from an end of the extension portion of the insulating layer and disposed on the substrate.

8. The semiconductor structure of claim 7, wherein the supporting pillar further penetrates the insulating wall.

9. The semiconductor structure of claim 1, wherein further comprising a supporting wall penetrating through the stacked structure and the insulating wall and disposed on the substrate, and extending in a plane direction of the substrate.

10. The semiconductor structure of claim 1, wherein further comprising a plurality of contacts respectively connected to an end of a corresponding conductive layer.

11. A manufacturing method of a semiconductor structure for a three-dimensional (3D) memory, comprising:
providing a substrate, wherein the substrate has an array region and a staircase region surrounding the array region;
forming an insulating wall surrounding the array region and the staircase region on the substrate; and
forming a stacked structure on the substrate in the array region and the staircase region, wherein the stacked structure comprises a plurality of insulating layers and a plurality of conductive layers alternately stacked,
wherein the plurality of insulating layers and the plurality of conductive layers conformally extend onto the insulating wall.

12. The manufacturing method of claim 11, wherein the insulating wall has a staircase profile and comprises a plurality of steps, and the plurality of insulating layers and the plurality of conductive layers conformally extend onto the plurality of steps.

13. The manufacturing method of claim 12, wherein:
each of the plurality of steps comprises a top surface and a sidewall,
each of the plurality of insulating layers and the plurality of conductive layers except the uppermost insulating layer comprises a body portion and an extension portion connected to the body portion, and the uppermost insulating layer comprises the body portion,
the extension portion of each of the plurality of insulating layers and the plurality of conductive layers except the uppermost insulating layer and the uppermost conductive layer comprises at least one first portion and at least one second portion, and the extension portion of the conductive layer comprises one second portion, wherein the first portion is disposed corresponding to the top surface, and the second portion is disposed corresponding to the sidewall, and
the uppermost second portion of each of the conductive layers except the uppermost conductive layer and the second portion of the uppermost conductive layer are exposed by the uppermost first portion of each of the insulating layers except the uppermost insulating layer and the body portion of the uppermost insulating layer.

14. The manufacturing method of claim 13, wherein top surfaces of the uppermost second portion of each of the conductive layers except the uppermost conductive layer and the second portion of the uppermost conductive layer are coplanar with top surfaces of the uppermost first portion of each of the insulating layers except the uppermost insulating layer and the body portion of the uppermost insulating layer.

15. The manufacturing method of claim 13, wherein:
each conductive layer has a first thickness,
each insulating layer has a second thickness,
the top surface of each step has a depth, and
a distance between centers of the second portions of two adjacent conductive layers is sum of the first thickness, the second thickness and the depth.

16. The manufacturing method of claim 13, wherein an end of the extension portion of the conductive layer is connected to an end of the body portion.

17. The manufacturing method of claim 13, further comprising forming a supporting pillar penetrating through the stacked structure from an end of the extension portion of the insulating layer and disposed on the substrate.

18. The manufacturing method of claim 17, wherein the supporting pillar further penetrates the insulating wall.

19. The manufacturing method of claim 11, further comprising forming a supporting wall penetrating through the stacked structure and the insulating wall and extending in a plane direction of the substrate.

20. The manufacturing method of claim 11, further comprising forming a contact at an end of each conductive layer.
